(19) United States
(12) Patent Application Publication
(10) Pub. No.: US 2012/0080087 A1
(43) Pub. Date: Apr. 5, 2012

(54) PHOTOVOLTAIC CELL

(76) Inventor: Phil Denby, Bergen (NO)

(21) Appl. No.: 13/263,204

(22) PCT Filed: Mar. 31, 2010
(86) PCT No.: PCT/NO10/00126

§ 371 Date: Dec. 19, 2011

(30) Foreign Application Priority Data
Apr. 6, 2009 (NO) 20091401

(51) Int. Cl. H01L 31/0224; H01L 31/18; B82Y 20/00; B82Y 40/00

(52) U.S. Cl. 136/256; 438/57; 257/E31.126; 977/948; 977/840

(57) ABSTRACT

A photovoltaic cell includes a first electrode and a second electrode operable to define an electric field (E) in a spatial region between the first electrode and the second electrode. Materials for fabricating the first electrode and the second electrode are chosen so that at least one is a metal, and that a material work function difference between these electrodes is of a sufficient magnitude to produce the electric field (E) without a need for selective doping of the electrodes. The spatial region includes one or more nano-particles (260) for receiving radiation, the nano-particles being operable so that the radiation excites surface plasmons in one or more nano-particles resulting in generation of one or more excited electrons for release from the one or more nano-particles and/or neighboring media to the one or more nano-particles and guided by the field (E) by way of nonconventional conduction processes to result in a current flow through the cell in response to receiving the radiation.

### FIELD OF THE INVENTION

The present invention relates to photovoltaic cells, for example to photovoltaic cells implemented as solar cells for converting electromagnetic radiation into electrical energy, to photovoltaic cells which are capable of storing their self generated power, and to radiation detectors which are not self-powered and are operable to generate a signal indicative of a magnitude and/or quantum energy of received electromagnetic radiation. Moreover, the invention also concerns methods of fabricating these photovoltaic cells. Furthermore, the invention relates to methods of utilizing these photovoltaic cells, and to systems employing these methods.

### BACKGROUND OF THE INVENTION

Silicon wafer technology was initially developed for manufacturing integrated circuits. Fabrication of contemporary photovoltaic cells from mono-crystalline or polycrystalline Silicon wafers benefits from processes evolved for fabricating integrated circuits. Such processes include, for example, epitaxial growth of heterostructures onto polished surfaces of Silicon wafers. The overall efficiency of Silicon photovoltaic cells manufactured from Silicon wafers is relatively low; only circa 17% of incident visible electromagnetic radiation received at a Silicon photovoltaic cell is converted to electrical power provided from the cell. The relatively low efficiency results from:
(a) Silicon exhibiting a relatively poor optical absorption, for example optical radiation penetrates a considerable distance of several microns into a surface of a Silicon wafer before being absorbed therein; and
(b) a relatively high probability of trapping charge carriers, within Silicon material.

By fabricating photovoltaic cells to be relatively thick for addressing issue (a), a greater number of traps are provided which exacerbate problems associated with issue (b). In order to reduce a number of traps for charge carriers, high efficiency photovoltaic cells are fabricated from mono-crystalline Silicon. Lower-efficiency photovoltaic cells utilize less expensive poly-crystalline Silicon for their manufacture.

Silicon semiconductor material has a relatively low band-gap energy resulting in a majority of absorbed radiation, for example sunlight, received at a Silicon photovoltaic cell at wavelengths longer than a cut-off wavelength of 1.1 μm being wasted. In comparison, Gallium Arsenide has a cut-off wavelength of 0.87 μm which is shorter than that of Silicon. A contemporary approach to improve photovoltaic cell operating efficiency is to employ stacked heterostructures, namely two of more photovoltaic cells fabricated into a stacked arrangement, wherein the photovoltaic cells are operable to absorb radiation most effectively at mutually different radiation wavelengths. Such heterostructures are more complex and costly to manufacture.

Incident electro-magnetic radiation is absorbed in an active region of a photovoltaic device and results in the generation of energetic conduction electrons thereat. These energetic electrons are free to flow through the conduction band in the device under an influence of an electric field present in the device. In a case of a radiation detector, it is customary for this electric field to be induced by an external source of potential difference. Conversely, in a case of a photovoltaic cell for energy production, the field is induced by the nature of the construction of the cell itself, namely typically involving some form of charge separation within one or more junctions formed between semiconducting layers within the device. Specifically as a result of n-type and p-type doping of semiconductor materials employed giving rise to a corresponding charge separation, a difference in the average energy of electrons at anode and cathode regions of the photovoltaic cell is generated which gives rise in operation to a current flow via anode and cathode output connections through the device, the current flow continuing until the average electron energy is equal on both sides of the photovoltaic cell.

As aforementioned, much of contemporary photovoltaic cell fabrication technology is reliant on the use of highly crystalline, high purity semiconductor wafer materials and associated processes. Use of these processes has reduced costs for the production of photovoltaic cells but still represents a major economic limitation which is hindering the extensive use of photovoltaic cells for electrical power generation as an alternative to burning fossil fuels for electricity generation. Research efforts regarding photovoltaic cell fabrication technology are increasingly moving away from more conventional semiconductor materials used for integrated circuit manufacture. More exotic semiconductor materials such as Gallium Arsenide represent a potential toxic hazard, especially if Gallium Arsenide devices become used to a wide extent within human society, for example for local solar power generation at home.

Metal nano-particles have been incorporated onto and into standard photovoltaic cells in order to improve their operation. A mechanism by which these nano-particles function to increase photovoltaic cell operating efficiency is still an area of much scientific debate.

Problems arising include at least one of:
(i) improving the operating efficiency of contemporary photovoltaic cells; and
(ii) reducing their cost of manufacture.

Recent enhancements in optical absorption characteristics enables photovoltaic cells to be considerably thinner than earlier more conventional photovoltaic cells which were reliant on bulk semiconductor materials, thereby reducing material costs as well as production time and energy required during manufacture. However, these recent enhancements have introduced many new additional problems such as localized short circuits between two or more electrodes layers when fabricating over a relatively large area of these photovoltaic cells.

In a published international PCT patent application WO 2007/118815A (CIBA Speciality Chemical Holdings Inc.), there is described a photovoltaic cell of high efficiency using metallic nano-particles or nano-structures as a main light-absorbing component in the photoensitive layer of the cell. The cell absorbs light incident upon the cell in operation through a surface Plasmon or polaron mechanism. The cell comprises at least one photosensitive layer including nano-particles or nano-structures each between a n-doped and p-doped charge transport layer, wherein:
(i) the nano-particles or nano-structures are the main light absorbing element in the photosensitive layer;
(ii) the nano-particles or nano-structures have metallic conductivity and absorb near infrared, visible and/or ultraviolet light through a surface Plasmon or polaron mechanism; and
(iii) the nano-particles or nano-structures have at least one or their dimensions of size between 0.1 nm and 500 nm. By exploiting a combination of electronic parameters, intense optical absorption at any wavelength within the solar spectrum, namely from about 2500 nm wavelength to 300 nm wavelength, can be obtained and thus the whole of the solar spectrum may be used for generating electricity.

Alternative approaches to those proposed in the PCT patent application WO 2007/118815A (CIBA Speciality Chemical Holdings Inc.) are possible which do not employ doped materials and which provide other synergistic benefits.

### SUMMARY OF THE INVENTION

An object of the present invention is to provide an improved type of photovoltaic cell which represents a marked step away from known types of photovoltaic cells and which provides additional synergistic benefits during operation.

According to a first aspect of the invention, there is provided a photovoltaic cell as defined in appended claim 1: there is provided a photovoltaic cell including a first electrode and a second electrode operable to define an electric field (E) in a spatial region between the first electrode and the second electrode,

characterized in that

materials for fabricating the first electrode and the second electrode are chosen so that at least one is a metal, and that a material work function difference between these electrodes is of a sufficient magnitude to produce the electric field (E); and

the spatial region includes one or more nano-particles (260) for receiving radiation, the nano-particles being operable so that the radiation excites surface plasmons in one or more nano-particles resulting in generation of one or more excited electrons for release from the one or more nano-particles and/or neighbouring media to the one or more nano-particles and guided by the field (E) by way of non-conventional conduction processes (for example by way of tunneling or hopping between material defects) in the spatial region to result in a current flow through the cell in response to receiving the radiation.

The invention is of advantage in that the photovoltaic cell is capable of being fabricated from materials which function in a different manner to semiconductor materials when employed to form junctions in contemporary photovoltaic cells.

The present invention makes use of tunnelling and/or hopping between electron/hole traps and/or lattice defects in the spatial region in contradistinction to conventional photovoltaic cells which utilize conduction by way of a conduction band of semiconductor layers employed. In other words, photovoltaic cells manufactured pursuant to the present invention function in a completely different manner to known types of photovoltaic cells.

The invention offers the potential for a “semiconductor free” or “all metal” or “metal-spray-on” solar cell. The environmental impact of this form of solar cell production and associated long-term disposal and recycling point of view is highly beneficial in comparison to the previously-used environmentally hazardous materials, for example associated with more conventional semiconductor technology. For example, the present invention is capable of avoiding a need to employ highly toxic materials such as Arsenic, heavy metals such as Cadmium, and other hazardous and toxic process chemicals such as Chlorofluorocarbon and Hydrogen Fluoride.

Optionally, the photovoltaic cell is implemented so that the one or more non-conventional conduction processes includes one or more of:
(i) tunnelling between electron/hole traps and/or lattice defects in the spatial region;
(ii) hopping between electron/hole traps and/or lattice defects in the spatial region;
(iii) tunnelling directly from the one or more nano-particles (260) to one or more of the first and second electrodes;
(iv) hopping directly from the one or more nano-particles (260) to one or more of the first and second electrodes; and
(v) tunnelling and/or hopping between material defects.

Optionally, the photovoltaic cell is implemented such that the materials for fabricating the first electrode and the second electrode are chosen so that at least one is a metal, and that a material work function difference between these electrodes is of a sufficient magnitude to produce the electric field (E) without a need for selective doping of the electrodes.

Optionally, for achieving suitable surface plasmon excitation and corresponding excited electron generation, the photovoltaic cell is implemented so that the one or more nano-particles have an average diameter which is in a range of 1 nm to 1000 nm.

Optionally, in the photovoltaic cell, the one or more nano-particles are fabricated from at least one of: insulator material, semiconductor material, metal material.

Optionally, in the photovoltaic cell, the one or more nano-paticles are disposed directly onto one of the electrodes of the cell.

Optionally, in the photovoltaic cell, the one or more nano-particles are individually surrounded by at least one encapsulating layer therearound, the at least one encapsulating layer being at least one of: an insulator, a semiconductor, a metal.

Optionally, the cell is adapted to be formed on a substrate, the substrate being operable to transmit radiation incident upon the cell to the active region.

Optionally, the cell is adapted to be formed on a substrate, the substrate being opaque to radiation to which the cell is responsive.

According to a second aspect of the invention, there is provided a method of operating a photovoltaic cell pursuant to the first aspect of the invention, the method including:
(i) fabricating the cell to include three-dimension convolution to enhance electrode surface areas within the cell for increasing a capacitance exhibited by the cell when in operation;
(ii) providing an opportunity for charges to accumulate on electrodes of the cell; and
(iii) coupling an external load to the cell to receive electrical charge stored in the cell.

By utilizing microstructuring and nano-structuring of the two electrode layers, an enhancement in their mutual surface area is susceptible to resulting in a significant increase in capacitance of the cell, thereby enabling the cell to function synergistically as a converter of solar radiation to electrical energy and then as a store for the electrical energy. In particular, it is noted that a large “2D” (planar) surface area is already available by nature of a photovoltaic device being adapted for solar energy collection. Such additional “3D” surface structuring can be achieved with minimal increase in the bulk of such cells, but with dramatic increase in their electrical storage potential. Comparison is made to supercapcitors developed by a company EEstor Inc. and as described on a granted patent no. U.S. Pat. No. 7,595,109B (Weir & Nelson).

According to a third aspect of the invention, there is provided a method of fabricating a photovoltaic cell pursuant to the first aspect of the invention, the method including:
(a) depositing or forming a first electrode layer on a substrate;
(b) etching to form additional nano-structures on the first electrode layer;
(c) selectively passifying the first electrode layer;
(d) depositing or forming an active layer onto the first electrode layer; and
(e) depositing or forming a second electrode layer onto the active layer,

wherein

the first and second electrode layers are operable to generate an electric field within the cell; and

the active layer includes one or more nano-particles for receiving radiation, the nano-particles being operable so that the radiation excites surface plasmons in one or more nano-particles resulting in generation of one or more excited electrons for release from the one or more nano-particles and/or neighbouring media to the one or more nano-particles and guided by the field by way of non-conventional conduction processes to result in a current flow through the cell in response to receiving the radiation.

Optionally, the method is implemented to fabricate the photovoltaic cell so that the one or more non-conventional conductions processes includes one or more of:
(i) tunnelling between electron/hole traps and/or lattice defects in the spatial region;
(ii) hopping between electron/hole traps and/or lattice defects in the spatial region;
(iii) tunnelling directly from the one or more nano-particles to one or more of the first and second electrodes;
(iv) hopping directly from the one or more nano-particles to one or more of the first and second electrodes; and
(v) tunnelling and/or hopping between material defects.

According to a fourth aspect of the invention, there is provided a photovoltaic cell pursuant to the first aspect of the invention, wherein the photovoltaic cell includes additional structures for enabling an additional potential to be applied in operation to a layer of the cell including nano-particles for influencing surface plasmon resonances of these nano-particles, thereby shifting and/or negating their optical absorption.

Optionally, the additional structures are implemented using first and second electrodes of the photovoltaic cell, or by inclusion of a third electrode disposed in such manner to produce an electric field which permeates an active layer of the cell including the nano-particles.

According to a fifth aspect of the invention, there is provided a method of utilizing a photovoltaic cell pursuant to the first aspect of the invention, for constructing a solar cell and/or radiation detector, the method including:
(a) mounting the photovoltaic cell on a support structure for enabling incident electromagnetic radiation to reach the cell in operation; and
(b) coupling electrical connections to the cell for receiving an electrical signal generated by the cell when in operation.

According to a sixth, aspect of the invention, there is provided an electrode geometrical grid arrangement for producing a fuseable network for an electrode of a photovoltaic cell, for example for a photovoltaic pursuant to the first aspect of the invention, wherein the electrode grid arrangement is operable when applied in respect of layers of two electrodes to be selectively fuseable in one or more regions thereof for isolating short circuits between the layers of the two electrodes.

It will be appreciated that features of the invention are susceptible to being combined in any combination without departing from the scope of the invention as defined by the appended claims.

### DESCRIPTION OF THE DIAGRAMS

Embodiments of the present invention will now be described, by way of example only, with reference to the following diagrams wherein:

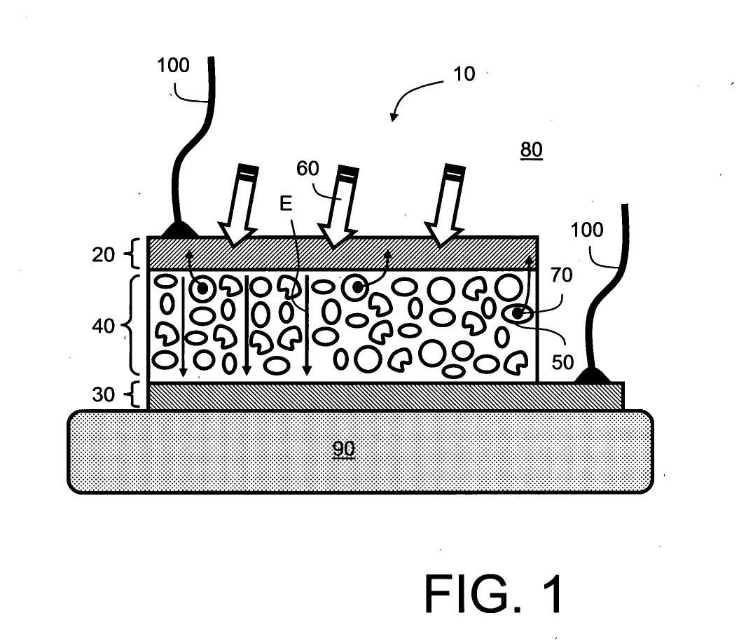

FIG. 1 is a schematic illustration of a photovoltaic cell pursuant to the present invention;

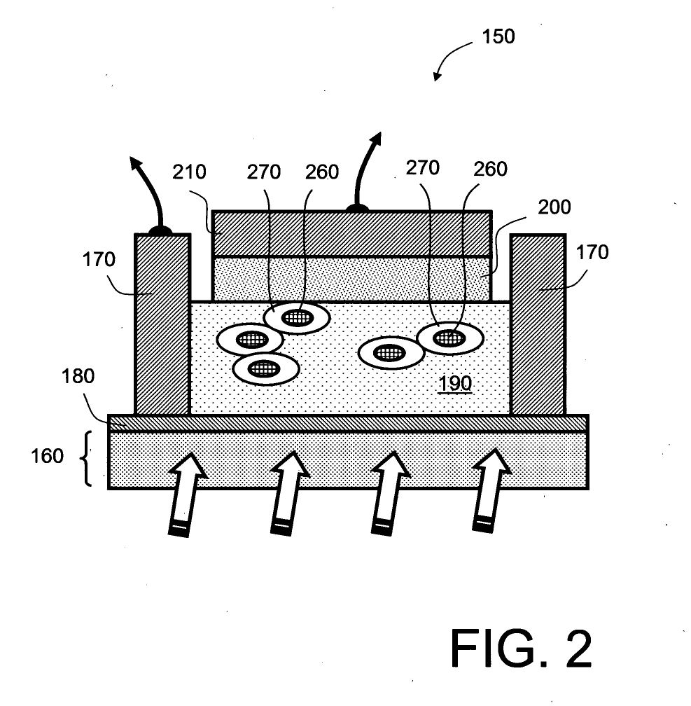

FIG. 2 is an illustration of a first embodiment of a photovoltaic cell pursuant the present invention adapted for fabrication on radiation-transmissive substrates;

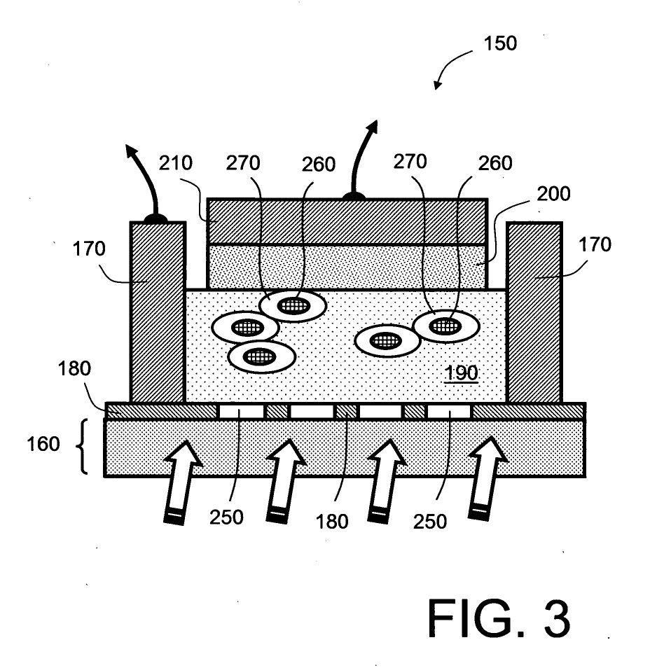

FIG. 3 is an illustration of the first embodiment of the photovoltaic cell of FIG. 2 but with an addition of holes provided in its first contact layer;

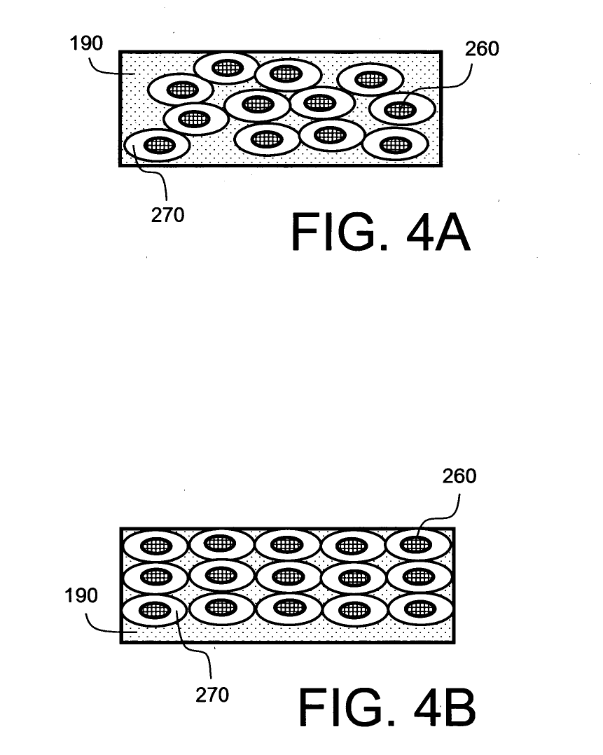

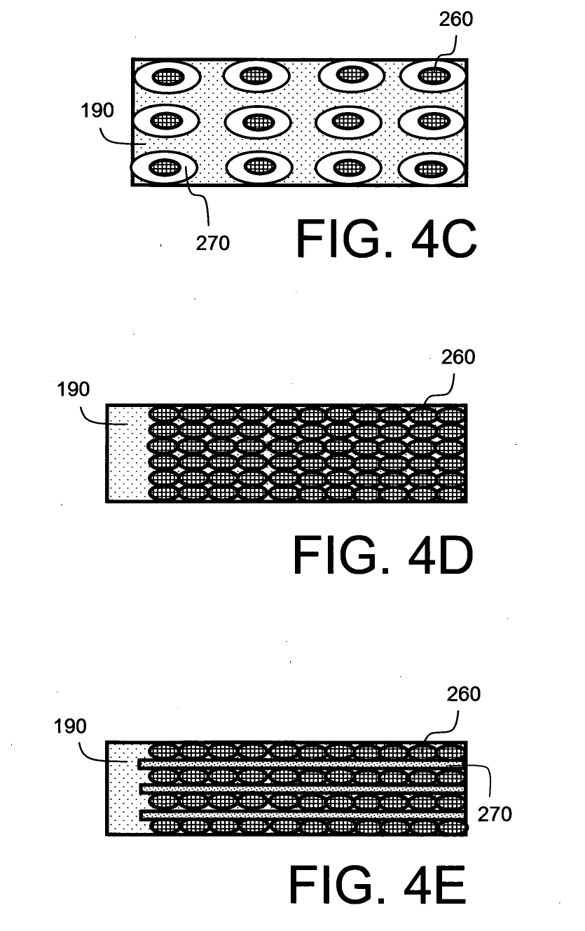

FIG. 4A to FIG. 4E are schematic illustrations of distributions of particles within an active region of the cells of FIGS. 1, 2, 3, and 5;

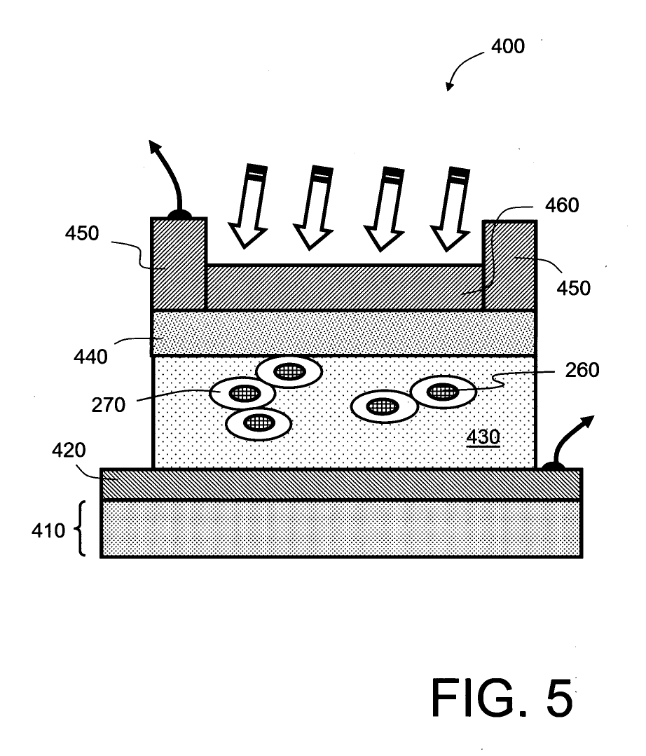

FIG. 5 is an illustration of a photovoltaic cell pursuant to a second embodiment of the present invention adapted for fabrication on radiation-opaque substrates;

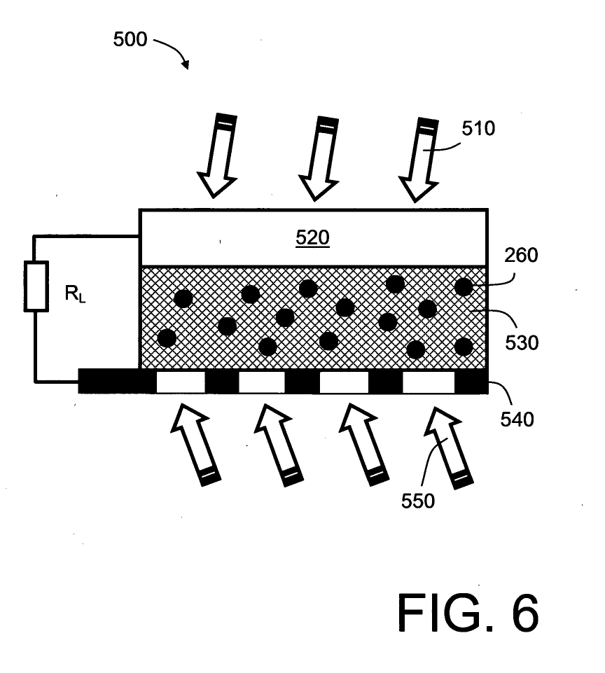

FIG. 6 is an illustration of a photovoltaic cell pursuant to a third embodiment of the present invention adapted to utilize a semi-transparent grid-like electrode structure;

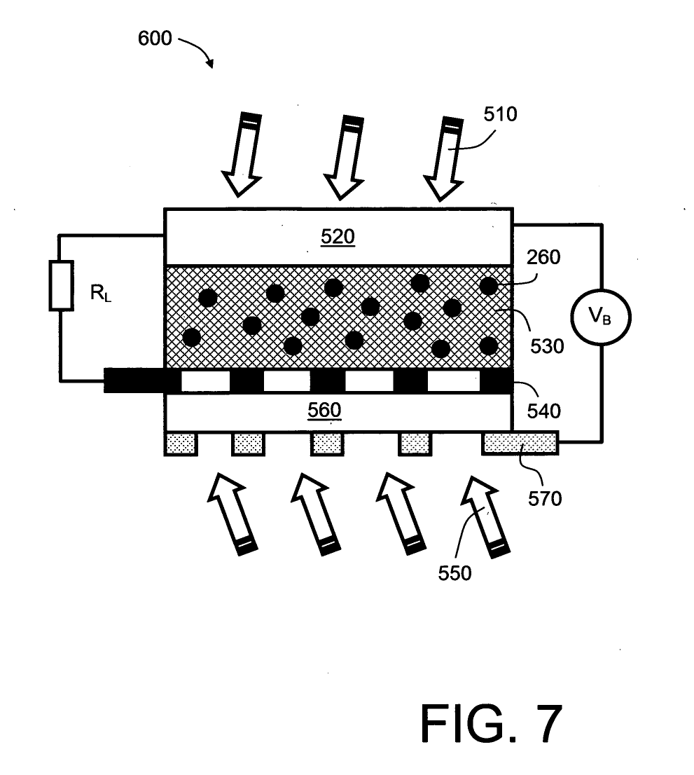

FIG. 7 is an illustration of a photovoltaic cell pursuant to a fourth embodiment of the present invention, the cell including a third electrode for applying an electric field to nano-particles of the cell for modulating their optical appearance and/or their optical response;

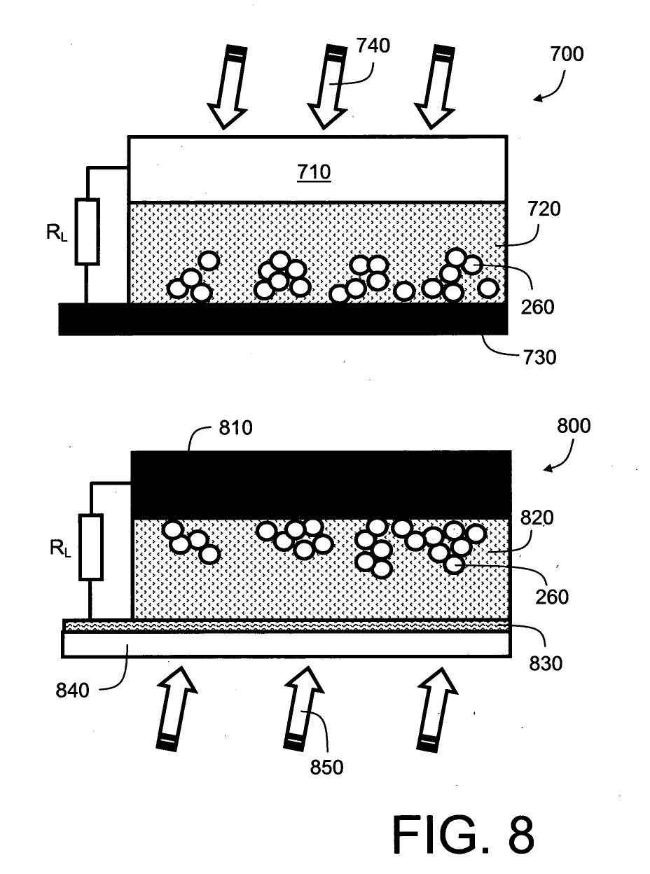

FIG. 8 is an illustration of a further pair of photovoltaic cells pursuant to fifth and sixth embodiments of the present invention;

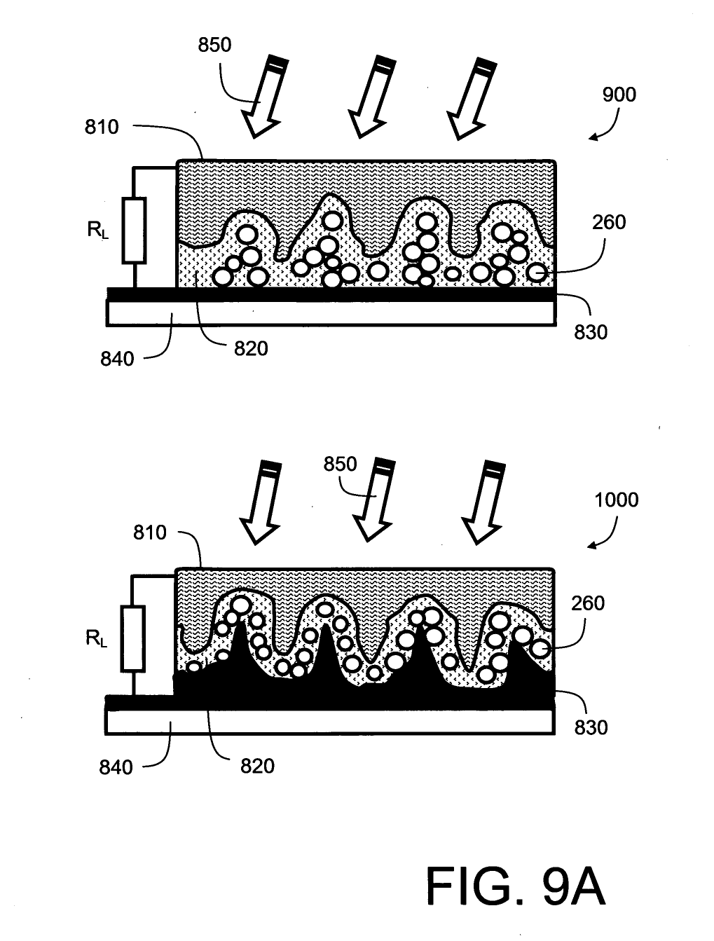

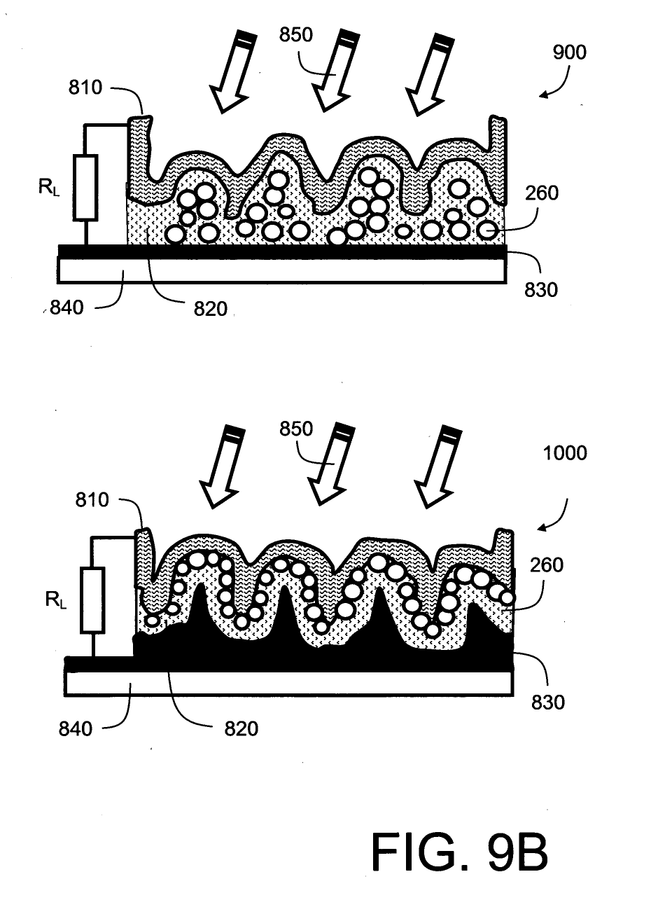

FIG. 9A is an illustration of a further pair of photovoltaic cells pursuant to seventh and eighth embodiments of the present invention, the cells including convoluted profiles for increase cell capacitance;

FIG. 9B is an illustration similar to FIG. 9A, with a modification that consecutive layers of the photovoltaic cell conform to a profile of an underlying layer of the cell;

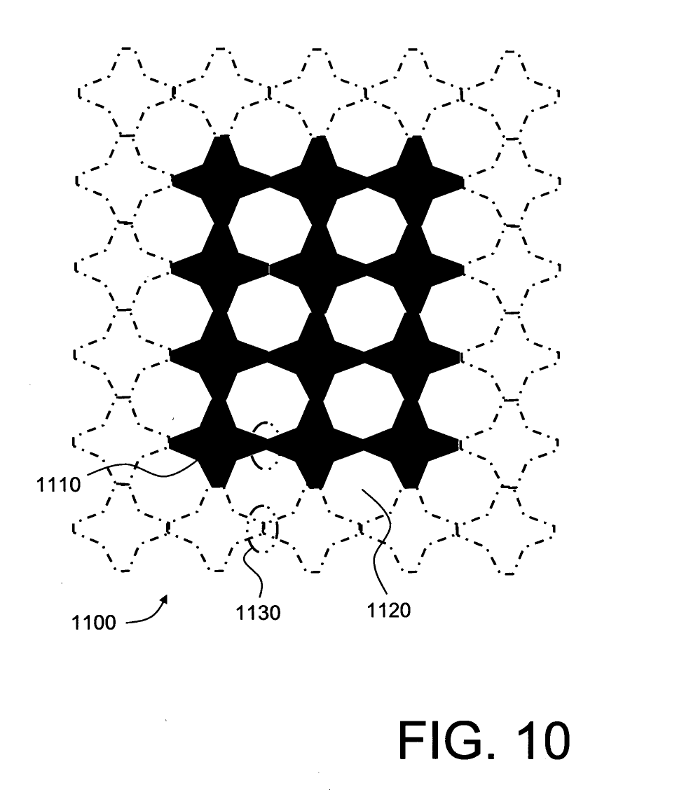

FIG. 10 is an illustration of a grid-type electrode for use as a fuseable network for use in isolating defective localized regions of photovoltaic cells pursuant to the present invention;

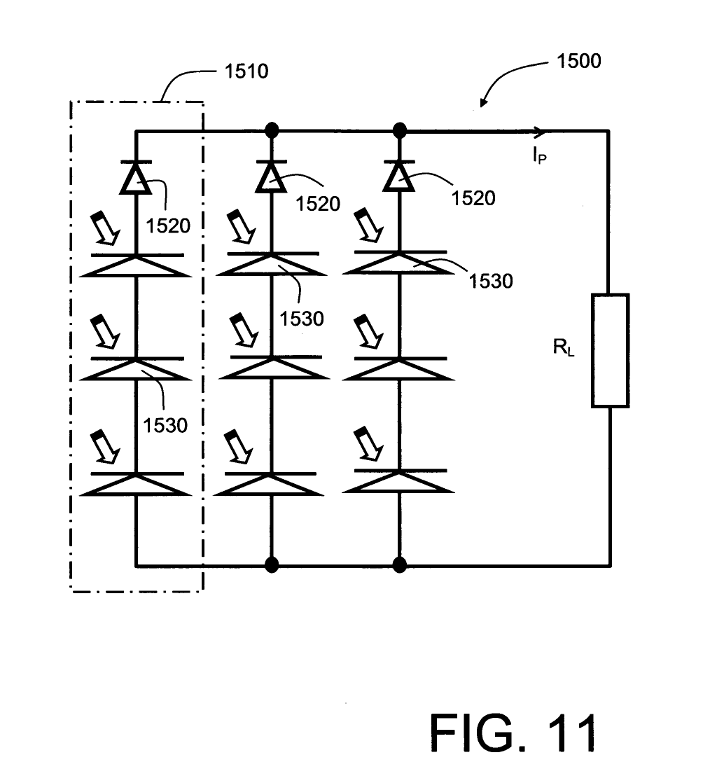

FIG. 11 is an illustration of a first application circuit for photovoltaic cells pursuant to the present invention; and

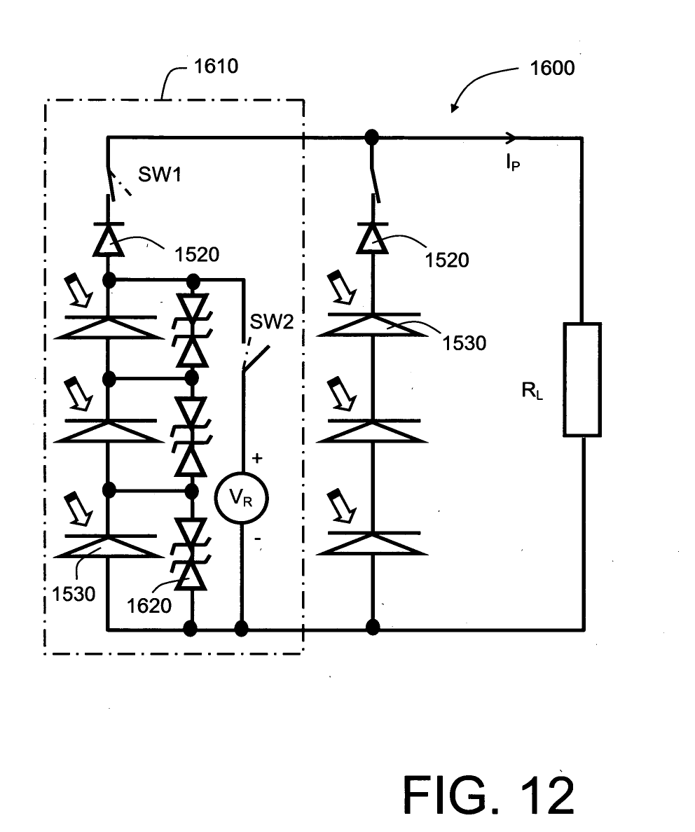

FIG. 12 is an illustration of a second application circuit for photovoltaic cells pursuant to the present invention.

In the accompanying diagrams, an underlined number is employed to represent an item over which the underlined number is positioned or an item to which the underlined number is adjacent. A non-underlined number relates to an item identified by a line or a bracket linking the non-underlined number to the item. When a number is non-underlined and accompanied by an associated arrow, the non-underlined number is used to identify a general item at which the arrow is pointing.

### DESCRIPTION OF EMBODIMENTS OF THE INVENTION

In the present invention, the inventor has devised a photovoltaic device which operates in manner which is completely different and distinct from conventional semiconductor junction-based photovoltaic devices as will now be explained in detail.

The present invention is based upon the use of nano-particles for fabricating photovoltaic cells. When electromagnetic radiation is received at a nano-particle, surface plasmon polaritons are excited on the nano-particle; hereinafter, surface plasmon polaritons will be referred to as “surface plasmons”. These surface plasmons are able to de-excite via coupling their energy into electrons in the neighbouring media; such coupling of energy is believed to occur in a very short time-period in an order of femtoseconds. Moreover, such coupling may occur directly within the nano-particle itself, or at some small distance from the nano-particle, for example within the neighbouring medium to the nano-particle. Furthermore, such coupling is operable to produce electrons with sufficient energy so that a majority of the electrons migrate, tunnel or hop through material used to fabricate the photovoltaic cell and thus to contribute to an external electrical current therefrom; such electron movement is to be contrasted to conventional mechanisms of electron conduction through a semiconductor conduction band of host material used to fabricate a conventional type of photovoltaic cell. In other words, the one or more energetic electrons are either generated within the nano-particle itself within a region surrounding the nano-particle, or may be extracted from an adjacent electrode layer by way of a mechanism of an intense localized electric field produced as a result of this surface Plasmon resonance, for example:
(a) in an encapsulating layer of the nano-particle; or
(b) in a separate layer or adjacent layer relative to the nano-particle.

The inventor has thus devised an alternative type of photovoltaic cell indicated by 10 in FIG. 1. The cell 10 has an internal electric field E which is generated by a contact potential difference between a first metallic and/or semiconductor layer 20 and a second metallic and/or semiconductor layer 30 disposed on either side of an active layer 40. For example, the layers 20, 30 are beneficially implemented from at least one of: Indium-Tin-oxide, Zinc oxide, or a thin high-workfunction metal, such as Gold, Silver or Copper, paired with a conducting layer of a low-workfunction metal such as Magnesium to mention a few examples. Moreover, the active layer 40 includes nano-particles 50 which actively absorb radiation 60 which penetrates in operation into the cell 10 via one or more of the aforementioned first and second layers 20, 30. The nano-particles 50 are most preferably metallic in nature, for example a pure metal, a metal alloy, a metal oxide, a metal halide, an organic metal compound. This absorbed radiation 60 is capable of:
(a) causing surface plasmons to be generated and consequently one or more energetic electrons 70 to be directly emitted from a given nano-particle 50 in the active layer 40, or from neighbouring material to the nano-particle 50 such as an encapsulating layer, for example less than 10 nm away from an external surface of the nano-particles 50; or
(b) being transferred to energy of electrons in surrounding material 80 to the cell 10.

On account of absorption of radiation within the nano-particles 50 being very intense, for example on account of their metallic nature when implemented from metallic material, the thickness of the active layer 40 can beneficially be reduced for enabling direct tunnelling or hopping between charge traps in the layer 40 of the one or more energetic electrons 70 and thus enabling the contact potential difference and its associated electric field E to influence the one or more energetic electrons 70; such a manner of operation is completely different in comparison to a manner of operation of a-conventional photovoltaic cell based upon a semiconductor junction between doped, semiconductor material layers.

As a result of such a completely different manner of operation, the cell 10 does not exhibit any specific cut-off wavelength effects observed for conventional photovoltaic cells, namely conventional photovoltaic cells exhibiting a minimum cut-off energy imposed by a band-gap energy of a semiconductor employed to fabricate a conventional semiconductor photovoltaic cell. In consequence, less energy is lost from more energetic photons absorbed into the active layer 40 of the cell 10, thereby enhancing cell operating efficiency.

The cell 10 is capable of being fabricated onto diverse substrates 90, for example inexpensive silica glass, ceramic substrates, metal sheet substrates or flexible polymer substrates. Moreover, the cell 10 employs metal deposition processes which are well characterized and perfected, for example for various contemporary industrial applications, for example processes such as magnetron coating of float glass or reel-to-reel coating of flexible material. Optionally, the cell 10 can be fabricated using “spray on” techniques, thereby no longer being limited by the sizes, shapes and expense of conventional semiconductor substrates, for example semiconductor wafers. For example, at least a part of the cell 10 is capable of being fabricated by using printing processes, for example high-speed non-contact ink-jet type spray printing. For providing a robust electrical connection to the cell 10, two thick electrically conductive contacts 100 can be additionally provided for the cell 10.

Referring to FIG. 2, there is shown an example embodiment of a photovoltaic cell pursuant to the present invention indicated by 150. The cell 150 represents a practical implementation of the cell 10 of FIG. 1. The cell 150 comprises a radiation-transparent substrate 160 through which radiation for exciting the cell 150 is transmitted in operation. Electrically-conductive connections to the cell 150 are denoted by 170; the connections 170 serve to provide an electrical connection to a first electrically-conductive layer 180 formed upon the substrate 160 as illustrated. The cell 150 further comprises an active layer 190 formed upon a surface of the first electrically-conductive layer 180 remote from the substrate 160 as illustrated. Moreover, the cell 150 further includes a second electrically-conductive layer 200 formed upon the active layer 190 and remote from the first electrically-conductive layer 180 as illustrated. Furthermore, the cell 150 further includes an electrically-conductive contact layer 210 formed onto the second electrically-conductive layer 200 remote from the active layer 190 as illustrated. Optionally, the cell 150 can be covered in a protective layer, for example in an organic polymeric passivating layer such as polyimide, or a robust inorganic layer such as Aluminium oxide. The electrically-conductive connections 170 are electrically isolated via the active layer 190 from the second electrically-conductive layer 200 and its associated contact layer 210 so that the cell 150 is operable to generate a potential between the connections 170 and the contact layer 210.

The first electrically-conductive layer 180 functions in cooperation with the second electrically-conductive layer 200 to generate an electric potential across the active layer 190, namely an electric field E. The first electrically-conductive layer 180 is sufficiently thin to enable incident radiation transmitted through the substrate 160 to pass through the first layer 180 to reach the active layer 190, namely the first layer 180 is substantially transparent or semi-transparent to the incident radiation; such transparency or semi-transparency can be achieved by forming the first layer to be up to a few ten's of nanometres thick. Optionally, the first layer 180 is, patterned to include one or more holes 250 as illustrated in FIG. 3 for transmitting incident radiation; when the one or more holes 250 are present in the first layer 180 for transmitting radiation to the active layer 190, a remainder of the first layer 180 is optionally made relatively thick, for example up to 500 nm thick, to enhance its current-carry ability even though it will be non-transparent in areas surrounding the one or more holes 250. Optionally, the holes 250 constitute at least 50% of a total area extent of the first layer 180, more beneficially at least 70% of the total area extent of the first layer 180.

The active layer 190 includes nanometre-sized particles 260 having a size, namely mean diameter, in a range of 1 nm to 1000 nm which function as an optical absorber for the cell 150. More optionally, the nanometre-sized particles 260 have a mean diameter in a range of 2 to 1000 nm, more preferable in a range of 2 to 500 nm. Yet more optionally, the nanometre-sized particles 260 have a mean diameter in a range of 3 to 250 nm. The mean diameter can be beneficially selected to modify radiation 60 wavelengths to which the cell 10 is most responsive. Nano-particle mean diameters of less than 1 nm can potentially be employed if necessary, but then begin to approach atomic size.

The particles 260 are optionally at least one of: an insulating material (for example silica), a, semiconductor material (for example Silicon), a metallic material (for example Magnesium, Gold, Titanium, Aluminium) and may preferably be of the same material as one of the electrically-conductive layers, namely 200 or 180. The particles 260 are most preferably metallic, although they are also optionally semiconductor material; for example, the particles 260 can be optionally fabricated substantially from Titanium dioxide although other materials are also susceptible to being used.

Optionally, the particles 260 are included in the active layer 190 in a purely spatially random fashion as illustrated in FIG. 4A; alternatively, the particles 260 are included in the active layer 190 in an organized spatially systematic fashion as illustrated in FIG. 4B. The particles 260 are optionally at least partially spatially isolated from one another as illustrated in FIG. 4C, for example by a binding medium. Alternatively, the particles 260 are arranged so that they mutually spatially abut one another as illustrated in FIG. 4D. Optionally, the particles 260 are all insulated from one another by a form of intermediate isolating layer 270 as illustrated in FIG. 4E. Optionally, the intermediate isolating layer 270 is integral to the particles 260, for example the isolating layer 270 is formed onto the particles 260 as part of a process whereby they are deposited to form the active layer 190. Use of the isolating layer 270 beneficially reduces an occurrence of short-circuited cells during manufacture.

Thus, the particles 260 are optionally arranged in groups of touching particles. Optionally, the particles 260 or groups of particles 260 are coated by a thin outer layer from a material which has been chemically derived from a material from which the particles 260 themselves are produced. Alternatively, this thin outer layer is added to the particles 260. This thin outer layer may be metallic, semiconductor or insulator which is optionally derived from one or more of the other materials used in photovoltaic cell construction, for example when employing a Magnesium electrode in the cell, Magnesium Oxide may be employed as an insulator; optionally, small modifications of deposition processes can be employed to generate such oxides, for example reactive sputtering instead of using inert sputtering. Yet more optionally, the further second thin outer layer is added to the particles 260 so that they are encapsulated within at least two layers. The further second thin outer layer is optionally semiconductor or insulator material. Optionally, the particles 260 and their encapsulating layers may be structured in the active region 190 as one or more layers of each, for example in a sandwich-type construction.

The second electrically conductive layer 200 is fabricated from metallic or semiconductor material. This second layer 200 in combination the first layer 180 define an electric field within the cell 150 as aforementioned.

In operation, radiation, for example incident sunlight, is transmitted through the substrate 160 to the active layer 190 wherein the radiation causes immediate generation of surface plasmons and then corresponding energetic electrons (“hot electrons”) as aforementioned. The energetic electrons are at least one of:
(a) generated within in the particles 260, wherein the energetic electrons escape from the particles 260 on account of the small size of the particles 260; and
(b) in a layer of material neighbouring onto or encapsulating each particle 260.

The escaped energetic electrons are then swept up by an electric field E generated by the contact potential of the cell 150. The energetic electrons are subsequently captured in at least one of the layers 180, 200 to give rise to an external current which can be extracted from the cell 150.

Referring to FIG. 5, there is illustrated an alternative implementation of a photovoltaic cell pursuant to the present invention; the cell is indicated generally by 400. The cell 400 represents a practical implementation of the cell 10. The cell 400 includes a radiation-opaque substrate 410, for example fabricated from metal sheet, an opaque glass sheet, a ceramic sheet, a polymer material sheet to provide a few examples. A first electrically-conductive layer 420 is included on the substrate 410, the substrate 410 optionally being metallic and/or semiconductor in nature. Moreover, an active layer 430 is included on the first layer 420 remote from the substrate 410 as illustrated; the active layer 430 is fabricated in a similar manner to the aforementioned active layer 190. Furthermore, onto the active layer 430 is included a second electrically-conductive layer 440 which is similar to the layer 180 of the cell 150. Optionally, the second layer 440 includes one or more holes in a similar manner to the holes 250 in the layer 180 of the cell 150 as described earlier, the one or more holes allowing transmission of incident radiation to the active layer 190. Electrical connections 450 are included at one or more locations on the second layer 440 as illustrated. Lastly, the cell 400 is provided with a transparent protective layer 460, for example fabricated from a polymer such as polyimide, vacuum-deposited glass or similar.

In operation, incident radiation, for example incident sunlight, is transmitted through the second layer 440 to the active layer 430 wherein the radiation causes immediate generation of surface plasmons and subsequently energetic electrons (“hot electrons”). Optionally, the energetic electrons are generated within the particles 260, wherein the energetic electrons escape from the particles 260 on account of the small size of the particles 260. Alternatively, the energetic electrons are generated in neighbouring media, for example a layer of material which at least partially encapsulates each particle 260. The escaped energetic electrons are then swept up by an electric field E generated by the contact potential of the cell 400. The energetic electrons are subsequently captured in at least one of the layers 420, 440 to give rise to an external current which can be extracted from the cell 400.

Optionally, the substrates 160, 410 are manufactured as wires, fibres or strips onto which the aforementioned associated layers are fabricated. Fabrication in “roll-good” form in a continuous manner is also feasible for enhancing cell production rate and/or for reducing production costs. The wires, ribbons or fibres are susceptible to being continuously produced and processed to form the cells 150, 400 as elongate devices which can be wound or woven into/onto a support frame which allows efficient exposure of, or promotes interconnection between, the wires, ribbons or fibres to incident radiation, for example sunlight; for example, the support frame is beneficially implemented as a conical structure, a cylindrical tower, a planar panel mountable to roofs of houses and/or vehicles, and similar. Moreover, subsidiary mirrors can be used to concentrate sunlight onto the cells 150, 400 to enable them to generate even more electrical output. On account of energetic (“hot electron”) emission at nanometre dimensions pursuant to the present invention not being strongly influenced by cell temperature, the cells 150, 400 are potentially able to operate at higher temperatures in comparison to contemporary semiconductor-junction photovoltaic cells. When large quantities of radiation are concentrated onto photovoltaic cells pursuant to the present invention, the cells are beneficially force-cooled with cooling fluid for reducing their temperature to avoid thermal damage thereto. Such cooling fluid is beneficially a material which can withstand an elevated temperature exceeding 100° C., thereby enabling the cells 150, 400 to be employed in solar arrays of “solar farms” for electrical power generation deployed in desert regions of the Earth's equator.

Optionally, arrays of the cells 150, 400 are manufactured such that any individual cells 150, 400 of such arrays which are defective in manufacture can be selectively disconnected, for example by laser, severing of connection tracks and/or fusing of connection tracks, so as to reduce waste when manufacturing the arrays.

Rear metallic contacts to the cells 150, 400, namely the layers 200, 420 respectively, are beneficially constructed, for example by using substantially transparent conductors or by employing the layers 200, 420 as grids with transparent holes, to enable the cells 150, 400 to appear transparent. Moreover, if the active layers 190, 430 optionally include an insulating material, for example Silicon dioxide with the nano-particles 260 embedded therein, it is feasible to match refractive indices of the cells 150, 400 to the refractive index of glass and thereby potentially avoid internal reflections between the cells 190, 430 and glass substrates thereof; by such matching, a need for complex antireflection coatings can be avoided. Conventional solar cells based upon Silicon semiconductor junction structures often require use of antireflection coatings for achieving adequate performance; the present invention is able to circumvent this requirement for anti-reflection coatings.

The cells 150, 400 are susceptible to being manufactured using combinations of various processes. For the production of the nano-particles 260 employed in the cells 150, 400, many contemporary industrial methods can be utilized, and the choice depends largely on the nature of the material of the nano-particles 260, and the best compatibility with the other components of the cells 150, 400. Processes for fabricating the cells 150, 400 beneficially employ at least one of:
(a) “sol-gel” synthesis, for example via chemical in-solution methods;
(b) ion implantation;
(c) milling, for example vacuum ion milling using inert gas ions;
(d) induced ion migration;
(e) self-assembly;
(f) vacuum deposition via nano-particle beam exposure.

As aforementioned, printing techniques, vacuum deposition, sputtering, electroplating, chemical etching and similar techniques are beneficially selectively employed when fabricating the cells 150, 400. Yet further fabrication methods which are optionally employed for constituent components of the cells 150, 400 include:
(a) in-solution synthesis;
(b) chemical vapour deposition;
(c) in-vacuuo techniques, such as “E-beam”, magnetron deposition, k-cell, thermal and ion-beam deposition.

More optionally, the cells 150, 400 are fabricated using in-vacuuo techniques based around magnetron deposition which are currently employed for large scale industrial coatings, and can also be adapted to the production of the nano-particles 260 themselves, for example via high-pressure magnetron operation. However, “spray-on” methods which are not dependent on obtaining a high-vacuum during cell fabrication are clearly economically highly attractive, for example silk-screen printing of electrodes on substrates using conductive inks, for producing the cells 150, 400.

The direction of the electric field E shown in the appended diagrams is only illustrative, and may be in an opposite direction depending on the nature of the materials employed.

In respect of the photovoltaic cells 10, 150, 400 described in the foregoing and variants thereof, it is feasible to “tune” surface Plasmon resonances of the nano-particles 260 by utilizing a suitable material selection for the nano-particles 260, by controlling a size of the nano-particles 260 as well as selecting suitable surrounding material to the nano-particles 260. Optionally, the cells 10, 150, 400 can be dynamically tuned in their response, for example by flexing a substrate of the cells 10, 150, 400 for actively modifying a separation distance between the particles 260, or by flexurally modifying the surrounding material to the nano-particles 260.

Such selection enables more wavelength specific absorption to be achieved. Moreover, photovoltaic cells may also thereby be manufactured to any desired colour, although such colour potentially may result in reduced efficiency in operation as a result of radiation of certain given wavelengths not being absorbed. Indeed, by tuning this absorption more locally, on a scale of millimetres for example, coloured patterning may be achieved within a single photovoltaic cell. This technique may simply be used to make the employment of such photovoltaic cells more aesthetically pleasing, making such cells completely red, or green for example to be better camouflaged, or pattering the cells themselves, with logos stripes and so forth. It may also be used for more practical benefits such as removing unwanted wavelengths from sunlight, infra-red/ultraviolet, for example, or indeed for the tinting of windows, but actively utilising the unwanted wavelengths for electrical energy generation. For example, photovoltaic cells pursuant to the present invention are susceptible to being manufactured to appear akin to roof tiles in profile and colour, thereby enabling ecologically-designed buildings to generate at least a part of their electrical power requirement from radiation incident thereupon.

The solar cells 150, 400, and other constructions for the cell 10 pursuant to the present invention, are susceptible to being employed for power generation and storage in diverse situations, for example from large-scale energy production (“solar farms”) to smaller-scale domestic application such as mobile battery chargers, mountain huts, summer houses, for the supply of electricity to remote equipment, environmental monitoring equipment, and even space technology such as satellite and space research probes.

When the cells 150, 400, and other implementations for the cell 10 pursuant to the present invention, are adapted to function as electromagnetic-radiation detectors, for example for measuring visible light for performing an optical intensity measurement, the cells 10, 150, 400 may even be optionally optimised for specific wavelength detection, for example as in imaging arrays for example, night-cameras, ultra-violet cameras and so forth. The cells 10, 150, 400 are thereby capable of being adapted to sense radiation beyond the human visible optical spectrum, for example when used for scientific monitoring. For example, the cells 10, 150, 400 are optionally disposed as an array for implementing a pixel image sensor, for viewing a scene via one or more suitable imaging lenses.

By active influence of surface plasmon resonance of nano-particles included within the aforementioned photovoltaic cells pursuant to the present invention, by application of an applied electric field, it is feasible to modulate conversion efficiency of the cells, and/or to modulate their adsorption and aesthetic appearance of the cells.

Embodiments of the present invention clearly lend themselves to more flexible applications, where essentially any surface may be coated in such a way as to make it function as a photovoltaic cell with electrical storage capacity. Such flexibility potentially opens up a huge new market to photovoltaic technology, in particular:
(a) for architectural and domestic use;
(b) for photovoltaic roofing tiles and other such “active” construction materials;
(c) for tinted windows including photovoltaic cells pursuant to the present invention which synergistically also actively harness, optical energy which is normally absorbed and wasted by the conventional tinted window.

The cells 150, 400, for example as manufactured using flat substrates, can be deployed as large arrays in “solar energy farms” for generating electricity from sunlight. The World is estimated to consume 80 million barrels of oil per day, wherein each barrel comprises 1.7 MW-hours of energy. This corresponds to an instantaneous power consumption of circa 5 TerraWatts (TW). Taking into consideration that sunlight falls onto Earth with an intensity of circa 500 Watts/square metre and that the cells 150, 400 are susceptible to being manufactured to exhibit a quantum conversion efficiency of around 50% or more, Earth's energy consumption from oil could be provided in a renewable manner by a 10000 square kilometre area populated with the cells 150, 400. With manufacturing cost benefits potentially provided by the present invention, its exploitation is of potentially enormous value to humanity by providing economical electrical power in a future post-fossil-fuel era.

From the foregoing, it will be appreciated that photovoltaic cells 150, 400 pursuant to the present invention are very different in comparison to conventional known photovoltaic cells. Cells 150, 400 pursuant to the present invention optionally do not utilize doping in a conventional manner, such doping being used in conventional devices to generate an internal field within devices and contributing additional charge carriers. In cells 150, 400 pursuant to the present invention, charging at internal surfaces of the metal electrodes, as a result of their contact potential difference, provides an internal electric field for the cells 150, 400. The internal electric field thereby assists to provide a route by which electrons released in operation at nano-particles 260 in response to plasmon interaction thereat are able to reach, by tunnelling and/or hopping operations, to the electrodes of the cells 150, 400 to contribute to a external current which the cells 150, 400 are able to deliver when in operation. First and second electrodes 180, 200, 420, 440 of the cells 150, 400 pursuant to the present invention include Magnesium paired with Gold, namely to provide the cells 150, 400 with a nominal unloaded potential of approximately 1.64 Volts. When fabricating the electrode layers 180, 200, 420, 440, a Gold layer of 20 nm thickness is suitably optically transmissive to enable incident photons to reach efficiently nano-particles 260 of the cells 150, 400; Gold has a further advantage in that it is chemically inert, thereby reducing any risk of long-term corrosion. However, other noble metals may be used in substitution for Gold with a drawback of a slightly reduced cell terminal voltage. With regard to Magnesium electrodes, these are beneficially deposited when fabricating the cells 150, 400 to a thickness of about 1 μm to render them sufficiently mechanically robust. Moreover, with respect of Copper electrodes of the cells 150, 400, these are deposited when fabricating the cells 150, 400 to a thickness between 250 nm to 1 μm, namely to provide sufficient mechanical protection to underlying layers including nano-particles 260.

As aforementioned, Magnesium oxide is a suitable insulating material to employ when fabricating photovoltaic cells 150, 400 pursuant to the present invention. Additionally, or alternatively, other insulating materials such as Titanium dioxide, Aluminium oxide, Silicon dioxide, Tungsten tri-oxide and similar are susceptible to being employed. These alternative materials are also susceptible to being deposited by sputtering processes for large-scale industrial mass production of the cells 150, 400. Additionally, these insulating materials are beneficially also selected in respect of advantageous dielectric constant for further enhancing a capacitance exhibited by the photovoltaic cell when in operation, and thus an ability of the cell to store its generated energy. The active layer 190, 430 of the photovoltaic cell including nano-particles 260 beneficially has a thickness between 100 nm to 1 μm, and more preferably in an order of 300 nm thickness. Overall, the photovoltaic cells 150, 400 pursuant to the present invention have a thickness between 1 μm to 2 μm, including contact electrode layers as well as the active layer 190, 430 including nano-particles 260.

When considering operation of photovoltaic cells 150, 400 pursuant to the present invention as described in the foregoing, it will be appreciated that a majority of current flow in operation arises not through carriers reaching a conduction band; but rather by way of tunnelling-conduction and hopping-conduction mechanisms. In other words, photovoltaic cells 150, 400 pursuant to the present invention function in an entirely different manner in comparison to convention Silicon doped junction photovoltaic cells.

Photovoltaic cells 150, 400 pursuant to the present invention optionally make use of a wide band gap semiconductor so that some current of the cell 150, 400 may potentially flow in a conventional manner through the conduction band of the cell 150, 400, although this is not a principal effect that occurs in the cells 150, 400 in their normal manner of intended operation. Beneficially, conduction through the conduction band of the cells 150, 400 is kept to a minimum when the cells 150, 400 are also required synergistically to store their own generated charge, for example to provide a charge reservoir to cope with surges of current demand from the cells 150, 400 when coupled to an external circuit, namely when the cells 150, 400 are being operating as a charge storage device. Comparison here for the cells 150, 400 is made to supercapacitors as aforementioned.

When fabricating the cells 150, 400, thin layers covering relatively large areas of substrate are employed. In consequence, occasional short circuits will occur directly between the electrode layers 180, 200, 420, 440, which are deleterious to operating efficiency of the cells 150, 400. During fabrication of the cells 150, 440, it is desirable to include features which enable defective parts of the cells 150, 400 to be isolated so that they do not degrade overall cell operating performance. Thus, the cells 150, 400 beneficially include grid-type electrodes including relatively thinner regions to promote local fusing for isolating defective areas. Such fusing action is beneficially achieved by applying a potential difference across the cells 150, 440 from a bias source as a next step after fabrication, the bias source being able to deliver sufficient current to fuse portions of the grid-type layer adjacent to short circuits. Embodiments of the cells 150, 400 employing such a fuseable grid-type layer will next be described.

An example embodiment of a photovoltaic cell pursuant to the present invention is illustrated in FIG. 6. The photovoltaic cell is indicated generally by 500 and is operable to convert incident upperside and lowerside optical radiation 510, 550 respectively into an electrical current for consumption by a load R_{L}. The photovoltaic cell 500 includes an upper thin metal or similarly semi-transparent/transparent electrode 520, an insulating layer 530 including nano-particles 260 distributed therein, and a lower thin semi-transparent metallic layer 540 which is transmissive to radiation by way of holes formed in the layer 540 as illustrated. The upper electrode 520 and/or the lower electrode 540 are formed onto a rigid substrate, for example a glass plate, a flexible polymer plastics material membrane or similar. In operation, the optical radiation 510, 550 is transmitted through one or more of the electrodes 520, 540 and reaches the nano-particles 260 to generate surface plasmons thereon. The plasmons give rise to electrons which experience an electric field E intrinsically generated within the cell 500 by way of the metals 520, 540 being mutually different in respect of electron density therein, the electric field E influencing the electrons by way of, for example, tunnelling and/or hopping events to contribute to an external current provided to the load R_{L}. The cell 500 is of benefit in that it can be illuminated in operation from underside and upperside, thereby enhancing its generating performance when employed in conjunction with solar reflectors.

The photovoltaic cell 500 of FIG. 6 is susceptible to being modified to provide a photovoltaic cell indicated generally by 600 in FIG. 7. In the photovoltaic cell 600, an isolating layer 560 of insulating material is included upon the grid-type electrode 540. Moreover, remote from the grid-type electrode 540, a second grid-type electrode 570 of conducting metal material is included onto the isolating layer 560. Beneficially, holes formed in the 570 are formed to coincide spatially with corresponding holes in the grid-type electrode 540 as illustrated for enabling light 550 to reach the nano-particles 260 efficiently. The electrode 570 is coupled via a voltage bias source V_{B} to the electrode 520. The electrode 540 is coupled via an external load to the electrode 520. In operation, light radiation received at the nano-particles 260 gives rise to an external current to the load R_{L} as previously described. The electrode 570 is biased by the source V_{B} to generate an electric field which partially penetrates into a region including the nano-particles 260, thereby modifying electron tunnelling and/or electron hopping events occurring within the layer 530. By varying a potential of source V_{B}, it is feasible to modify an output of the cell 600 to the load R_{L}, to change an optical transmission through the cell 600 and/or to change a colour of the cell 600. When the cell 600 is formed upon a transparent substrate, for example a glass substrate and/or a flexible plastics material substrate, it is feasible to use an array of the cells 600 to form a pixel array screen which is rendered visible by backlighting. The cell 600 is potentially able to perform better than a convention thin-film liquid crystal display screen which requires various light-polarizing layers in order to function correctly as an optical pixel display; such better performance includes, for example, more rapid pixel switching necessary for providing real-time 3-dimensional video images for viewing when the cell 600 is used to form active optical components in a display screen.

In FIG. 8, there is shown an embodiment of the present invention in a form of a photovoltaic cell indicated generally by 700. The photovoltaic cell 700 includes a first thin metal or similarly semi-transparent/transparent electrode 710, an insulating layer 720 including nano-particles 260, and a second metallic electrode layer 730. Optionally, the nano-particles 260 are mutually touching; such touching is of benefit in improving conduction through the cell 700. The layers 710, 730 are fabricated from mutually different metals for generating an intrinsic electric field across the insulating layer 720. The cell 700 is beneficially coupled to an external load R_{L} via the first and second electrode layers 710, 730. The nano-particles 260 are beneficially concentrated in a region abutting the second electrode layer 730 as illustrated. Beneficially, the second electrode layer 730 is formed on a substrate, for example a metal plate, a glass plate, a plastics material film or plate, a ceramic plate. Light 740 is incident in operation on the first electrode layer 710 and is transmitted therethrough to the nano-particles 260 to generate an external current through the load R_{L} by way of tunnelling and/or hopping events for “hot” electrons within the layer 720. An alternative embodiment of a photovoltaic cell is also illustrated in FIG. 8 and indicated generally by 800. The photovoltaic cell 800 includes a thick first metallic electrode layer 810, an insulating layer 820 including nano-particles 260, and a second metallic electrode layer 830 formed onto an optically transparent substrate 840. The metallic electrode layers 810, 830 are optionally fabricated from mutually different metals, for example Gold and Magnesium. The nano-particles 260 are beneficially substantially concentrated within the insulating layer 820 in a region adjacent to the second electrode layer 830 as illustrated. Light radiation 850 transmitted through the substrate 840 and also through the second electrode layer 830 is received at the nano-particles 260 whereat plasmons are excitied which give rise to electrons which are able to tunnel and/or hop to one or more of the electrode layers 810, 830 to generate an external current for the load R_{L}. Concentrating the nano-particles 260 close to the second metallic electrode 830 is beneficial for electron tunnelling and/or hopping events, thereby resulting in improved efficiency of operation of the photovoltaic cell 800. In order to increase capacitance of a photovoltaic cell pursuant to the present invention, one or more of the first and second electrode layers 810, 820 are beneficially provided with topographic projections into the insulating layer 820 as illustrated in photovoltaic cells indicated by 900, 1000 in FIG. 9A. Beneficially, the topographic projections have a width:length ratio in a range of 1 to 10000, depending upon a degree of capacitance desired. The projections are beneficially formed by sputtering and/or wet chemical electroplating operations and/or etching operations, for example via holes formed in an organic resist which is later at least partially removed, optionally forming a portion of the insulating layer 820. Optionally, these projections may themselves be made from a sintered composite layer of nano-particles. Nano-particles 260 are included within the insulating layer 820 to impart the photovoltaic cells 900, 1000 with their electrical current generating functionality by way of electron tunnelling and/or hopping events within the insulating layer 820. As illustrated in an upper portion of FIG. 9B, the nano-particles 260 and their associated insulating layer 820 are formed on a flat electrode 830, and the electrode layer 810 conforms to topography of a surface of the insulating layer 820 remote from the electrode layer 810. Moreover, as illustrated in a lower portion of FIG. 9B, the electrode layer 830 is fabricated to have a projecting topography onto which the insulating layer 820 with its nano-particles 260 is formed, and wherein the electrode layer 810 is then formed onto the insulating layer 820 as illustrated in a manner conforming to topography of the insulating layer 820. Implementations pursuant to FIG. 9B are capable of enhancing light penetration to the nano-particles 260 in the insulating layer 820 and thereby enhancing conversion efficiency of the cells 900, 1000.

Referring to FIG. 10, there is shown a grid-type implementation of one or more of the metallic electrode layers of photovoltaic cells as aforementioned pursuant to the present invention. The electrode layer in FIG. 10 is indicated generally by 1100 and is beneficially produced by shadow deposition, for example via vacuum evaporation via a stencil mask, by a photolithographic process followed by wet and/or dry etching, by light-induced spatially-selective deposition. The electrode layer 1100 is metallic and includes one or more non-conductive hole regions 1120 and one or more connection links have a thinnest fuseable portion 1130. In an event that a part of the electrode layer 1100 couples to an area of the insulating layer 820 whereat the nano-particles 260 are distributed so as to form an undesired direct short between the electrode layers 810, 830, an external current applied to the photovoltaic cell after its initial fabrication is used for selectively vapourizing fuseable portions 1130 of the electrode layer 1120 for isolating short circuits between the layers 810, 830 arising during manufacture. In an event that the photovoltaic cell subsequently develops a short circuit between its electrode layers 810, 830, a similar approach can be used later to repair the cell.

Photovoltaic cells pursuant to the present invention are susceptible to being used in diverse applications such as:
(i) electrical power generation from “solar farms”;
(ii) for emergency power generation at remote locations;
(iiii) for recharging vehicles, wherein the photovoltaic cells are a component part of a bodywork of vehicles; and
(iv) for manufacturing a pixel graphic display.

When employed for power generation, the photovoltaic cells pursuant to the present invention are beneficially configured in arrays including a plurality of the cells. These arrays are beneficially designed to be fault tolerant, namely failure of a single photovoltaic cell does not cause failure of the entire array. For example, in FIG. 11, there is provided an illustration of a photovoltaic cell array indicated generally by 1500, the array 1500 including a plurality of photovoltaic cells 1530 pursuant to the present invention. The cells 1510 are beneficially arranged in series groups 1510 which each feeds its generated current via an associated semiconductor diode 1520 to a load R_{L}. In an event that one or more cells 1530 fail along a given group 1510, the current contribution of that group 1510 becomes, decoupled by way of their diode 1520 becoming reverse biased, thereby enabling other functioning groups 1510 to contribute to current supplied to the load R_{L}. When the photovoltaic cells 1530 are fabricated in a manner as depicted in FIG. 9A together with at least one of its metallic electrodes implemented as illustrated in FIG. 10, any short circuit occurring within any one or more cells 1520 is immediately isolated by way of the fuseable portions 1130 being fused by charges stored in the cells 1520. Such self-fusing can occur so rapidly, for example within microseconds of a short circuit developing in operation, such that the current supply to the load R_{L} appears uninterrupted.

If additional protection is required to repair faulty cells 1530, a circuit configuration as indicated by 1600 in FIG. 12 is beneficially employed, wherein the photovoltaic cells 1530 are provided with bypass Zener diodes 1620, a first decoupling switch SW1, a second fusing switch SW2 and a fusing repair voltage source V_{R}. In an event that a group 1610 of cells 1530 develops one or more short circuit faults, the first switch SW1 is opened and then the second switch SW2 is closed causing a repair current to flow through the Zener diodes of functional cells 1530 and via the short circuits of faulty cells 1530, causing their fuseable portions 1130 to fuse, thereby isolating the short circuits afflicting the cells 1530. Optionally, the circuit configuration 1600 is subject to repeat intermittent connection to the repair voltage source V_{R} for disconnecting any short circuits that may develop during operation, for example due to ageing of materials and/or corrosion. Such intermittent connection is beneficially a part of a regular maintenance routine.

In the foregoing, the electric field E is beneficially of sufficient magnitude to ensure that the photovoltaic cells pursuant to the present invention exhibit a terminal voltage across their electrode layers not less than 0.1 Volt when they are exposed to strong radiation levels, for example in excess of 50 W/m².

Modifications to embodiments of the invention described in the foregoing are possible without departing from the scope of the invention as defined by the accompanying claims.

Expressions such as “including”, “comprising”, “incorporating”, “consisting of”, “have”, “is” used to describe and claim the present invention are intended to be construed in a non-exclusive manner, namely allowing for items, components or elements not explicitly described also to be present. Reference to the singular is also to be construed to relate to the plural.

Numerals included within parentheses in the accompanying claims are intended to assist understanding of the claims and should not be construed in any way to limit subject matter claimed by these claims.

1. A photovoltaic cell (150, 400, 500, 600, 700, 800, 900, 1000) including a first electrode and a second electrode operable to define an electric field (E) in a spatial region (190, 430, 530, 720, 820) between the first electrode and the second electrode,
characterized in that
materials for fabricating the first electrode and the second electrode are chosen so that at least one is a metal, and that a material work function difference between these electrodes is of a sufficient magnitude to produce the electric field (E); and
said spatial region (190, 430, 530, 720, 820) includes one or more nano-particles (260) for receiving radiation, said nano-particles (260) being operable so that the radiation excites surface plasmons in one or more nano-particles (260) resulting in generation of one or more excited electrons for release from the one or more nano-particles (260) and/or neighbouring media to the one or more nano-particles (260) and guided by the field (E) by way of one or more non-conventional conduction processes to result in a current flow through the cell (150, 400, 500, 600, 700, 800, 900, 1000) in response to receiving the radiation.

2. A photovoltaic cell (150, 400, 500, 600, 700, 800, 900, 1000) as claimed in claim 1, wherein said one or more non-conventional conduction processes includes one or more of:
(i) tunnelling between electron/hole traps and/or lattice defects in said spatial region (190, 430, 530, 720, 820);
(ii) hopping between electron/hole traps and/or lattice defects in said spatial region (190, 430, 530, 720, 820);
(iii) tunnelling directly from the one or more nano-particles (260) to one or more of the first and second electrodes;
(iv) hopping directly from the one or more nano-particles (260) to one or more of the first and second electrodes; and
(v) tunnelling and/or hopping between material defects.

3. A photovoltaic cell (150, 400, 500, 600, 700, 800, 900, 1000) as claimed in claim 1 or 2, wherein the materials for fabricating the first electrode and the second electrode are chosen so that at least one is a metal, and that a material work function difference between these electrodes is of a sufficient magnitude to produce the electric field (E) without a need for selective doping of the electrodes.

4. A photovoltaic cell (150, 400, 500, 600, 700, 800, 900, 1000) as claimed in claim 1, 2 or 3, wherein said one or more nano-particles (260) have an average diameter which is in a range of 1 nm to 1000 nm.

5. A photovoltaic cell (150, 400, 500, 600, 700, 800, 900, 1000) as claimed in claim 1, 2, 3 or 4, wherein said one or more nano-particles (260) are fabricated from at least one of: insulator material, semiconductor material, metal material.

6. A photovoltaic cell (150, 400, 500, 600, 700, ‘800, 900, 1000) as claimed in any one of the preceding claims, wherein said one or more nano-paticles (260) are disposed directly onto one of the electrodes of the cell.

7. A photovoltaic cell (150, 400, 500, 600, 700, 800, 900, 1000) as claimed in any one of the preceding claims, wherein said one or more nano-particles (260) are individually surrounded by at least one encapsulating layer (270) therearound, said at least one encapsulating layer (270) being at least one of: an insulator, a semiconductor, a metal.

8. A photovoltaic cell (150, 400, 500, 600, 700, 800, 900, 1000) as claimed in any one of the preceding claims, wherein said cell (150, 400) is adapted to be formed on a substrate, said substrate (160, 410) being operable to transmit radiation incident upon the cell (150, 400, 500, 600, 700, 800, 900, 1000) to the active region (190, 430, 820).

9. A photovoltaic cell (150, 400, 500, 600, 700, 800, 900, 1000) as claimed in any one of the preceding claims, wherein said cell (150, 400, 500, 600, 700, 800, 900, 1000) is adapted to be formed on a substrate, said substrate (160, 410) being opaque to radiation to which the cell (150, 400) is responsive.

10. A photovoltaic cell (150, 400, 500, 600, 700, 800, 900, 1000) as claimed in any one of the preceding claims, wherein one or more layers of the cell are formed to provide the cell with enhanced intrinsic capacitance for enabling the cell to store its generated electrical energy.

11. A photovoltaic cell (150, 400, 500, 600, 700, 800, 900, 1000) as claimed in any one of the preceding claims, wherein said nano-particles (260) are implemented so that their optical properties change in response to electric field being applied across them in operation.

12. A photovoltaic cell (150, 400, 500, 600, 700, 800, 900, 1000) as claimed in any one of the preceding claims, wherein an electrode grid arrangement is operable when applied in respect of layers of the two electrode layers to be selectively fuseable in one or more regions thereof for isolating short circuits between the layers of the two electrodes.

13. A photovoltaic cell (150, 400, 500, 600, 700, 800, 900, 1000) as claimed in any one of the preceding claims, wherein said cell (150, 400, 500, 600, 700, 800, 900, 1000) includes one or more additional structures for enabling an additional potential to be applied in operation to a layer including said nano-particles for influencing surface plasmon resonances of these nano-particles, thereby shifting and/or negating their optical absorption.

14. A method of fabricating a photovoltaic cell (150, 400, 500, 600, 700, 800, 900, 1000) as claimed in claim 1, said method including:
(a) depositing or forming a first electrode layer (180, 420) onto a substrate (160, 420);
(b) etching to form additional nano-structures on the first electrode layer (180. 420):
(c) selectively passifying the first electrode layer (180, 420);
(d) depositing or forming an active layer (190, 430, 820) onto the first electrode layer (180, 420); and
(e) depositing or forming a second electrode layer (220, 440) onto the active layer (190, 430),
wherein
said first and second electrode layers are operable to generate an electric field (E) within said cell; and
said active layer (190, 430, 820) includes one or more nano-particles (260) for receiving radiation, said nano-particles (260) being operable so that the radiation excites surface plasmons in one or more nano-particles resulting in generation of one or more excited electrons for release from the one or more nano-particles (260) and/or neighbouring media to the one or more nano-particles (260) and guided by the field by way of non-conventional current flow processes to result in a current flow through the cell (150, 400, 500, 600, 700, 800, 900, 1000) in response to receiving the radiation.

15. A method as claimed in claim 14, wherein said one or more non-conventional conduction processes includes one or more of:
(i) tunnelling between electron/hole traps and/or lattice defects in said spatial region (190, 430, 530, 720, 820);
(ii) hopping between electron/hole traps and/or lattice defects in said spatial region (190, 430, 530, 720, 820);
(iii) tunnelling directly from the one or more nano-particles (260) to one or more of the first and second electrodes;
(iv) hopping directly from the one or more nano-particles (260) to one or more of the first and second electrodes; and
(v) tunnelling and/or hopping between material defects.

16. A method of utilizing a photovoltaic cell (150, 400, 500, 600, 700, 800, 900, 1000) as claimed in any one of claims 1 to 13 for constructing a solar cell and/or radiation detector, said method including:
(a) mounting said photovoltaic cell (150, 400, 500, 600, 700, 800, 900, 1000) on a support structure for enabling incident electromagnetic radiation to reach said cell (150, 400, 500, 600, 700, 800, 900, 1000) in operation; and
(b) coupling electrical connections to said cell (150, 400, 500, 600, 700, 800, 900, 1000) for receiving an electrical signal generated by said cell (150, 400, 500, 600, 700, 800, 900, 1000) when in operation.

17. An electrode geometrical grid arrangement for producing a fuseable network for an electrode of a photovoltaic cell as claimed in any one of claims 1 to 13, wherein the electrode grid arrangement is operable when applied in respect of layers of two electrodes to be selectively fuseable in one or more regions thereof for isolating short circuits between the layers of the two electrodes.
